(19) United States
(12) Patent Application Publication
(10) Pub. No.: US 2008/0160800 A1
(43) Pub. Date: Jul. 3, 2008

(54) Pin with shape memory alloy

(76) Inventors: Wen Qi Dai, Shanghai (CN); Gang Jin, Shanghai (CN); Bernadette Undan, General Trias Cavite (PH)

Correspondence Address: INTEL/BLAKELY, 1279 OAKMEAD PARKWAY, SUNNYVALE, CA, 94085-4040, US

(21) Appl. No.: 11/648,211

(22) Filed: Dec. 29, 2006

(51) Int. Cl. H01R 12/12; H05K 1/09

(52) U.S. Cl. 439/81; 174/257

(57) ABSTRACT

A computing system comprises one or more system components, such as CPU, BIOS, storage devices, controllers, etc. The system components may be provided on a chipset or a motherboard. The system components are configured with pins made from shape memory alloy.

### BACKGROUND

Pin grid array (PGA) packages typically utilize pins to form external interconnects. However, pins may become bent during CPU or other package assembling and/or testing process. While pin reworking may recover some bent pins, other bent pins may be unrecoverable and scrapped. Since bent pins are necessary for pin material and test process, they can not be eliminated. Unfortunately, testing the units with bent pins that can not be recovered increases UPH time.

### BRIEF DESCRIPTION OF THE DRAWINGS

The invention described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

FIG. 1 is a schematic diagrams of an embodiment of a computing system.

FIG. 2 is a schematic diagram of an embodiment of a chip.

FIG. 3 illustrates another embodiment of a package that may utilize pins.

FIG. 4 illustrates an embodiment of a socket or port.

FIG. 5 illustrates an embodiment of a method that may be used to form the chip of FIG. 2.

FIG. 6 illustrates an embodiment of a method that may be used to form a chip that comprises the package 302 and the socket 304 of FIG. 3.

### DETAILED DESCRIPTION

In the following detailed description, references is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numbers refer to the same or similar functionality throughout the several views.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The following description may include terms, such as upper, lower, top, bottom, first, second, etc. that are used for descriptive purposes only and are not to be construed as limiting.

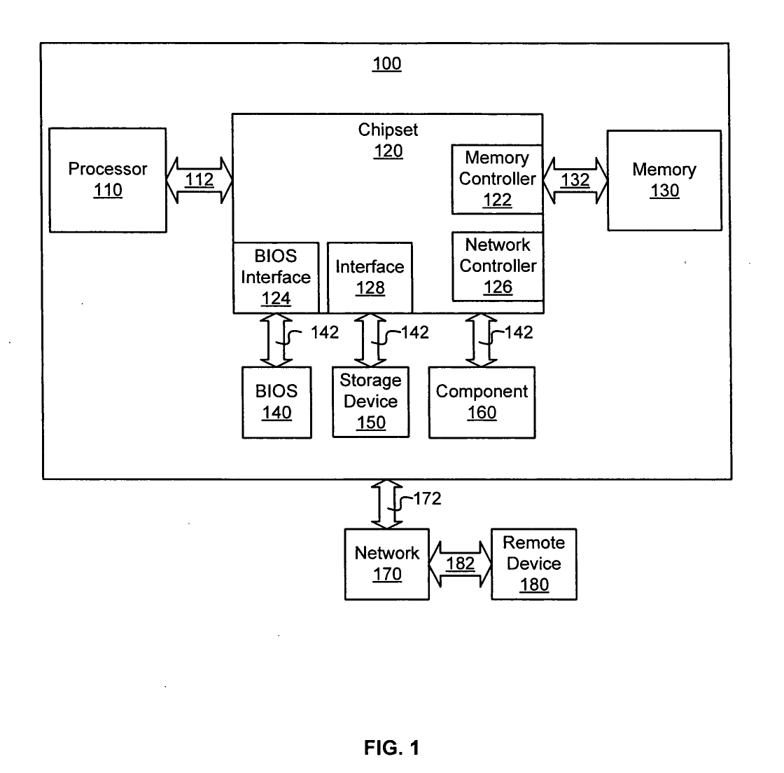

FIG. 1 shows an example embodiment of a computing device 100. The computing device 100 may comprise one or more processors 110. The processor 110 may perform actions in response to executing instructions. For example, the processor 110 may executes programs, perform data manipulations and control tasks in the computing device 100, etc. The processor 110 may be any type of processor adapted to perform operations in memory 130. For example, processor 110 may be a microprocessor, a digital signal processor, a microcontroller, or any other processors. In one embodiment, the processor 110 may be not dedicated to the use of memory 130, and the processor 110 may perform operations in memory 130 while also performing other system functions.

The memory 130 may comprise memory devices providing addressable storage locations that a memory controller 122 may read data from and/or write data to. The memory 130 may comprise one or more different types of memory devices such as, for example, dynamic random access memory (DRAM) devices, synchronous dynamic random access memory (SDRAM) devices, read-only memory (ROM) devices, or any other volatile or non-volatile memory devices.

The computing device 100 may further comprise a chipset 120. The chipset 120 may comprise one or more integrated circuit (IC) packages or chips that couple the processors 110 to memory 130, Basic Input/Output System (BIOS) 140, one or more storage devices 160, and other components (for example, mouse, keyboard, video controller, or other I/O devices of the computing device 100, etc.). The chipset 130 may receive transactions from the processors 110 and to issue transactions to the processors 110 via a processor bus 112. The memory controller 122 may issue transactions to the memory 140 via a memory bus 132.

In one embodiment, the storage device 160 may store archive information, such as code, programs, files, data, applications, or operating systems, etc. An example of the storage device 160 may comprise a tape, hard disk (HD) drive, a floppy diskette, a compact disk (CD) ROM, a flash memory device, any other mass storage device, any other magnetic storage media, any other optical storage media, any other non-volatile memory devices, etc. The chipset 120 may comprise one or more storage device interfaces 128 that may access each storage device 160 via a bus 142.

In one embodiment, the BIOS 140 may be used for system initialization and/or configuration of the computing device 100. In another embodiment, the BIOS 140 may collect information that may be selectively used by an operation system. For example, the information may comprise a data structure that may be used by the operation system to look up one or more devices in the computing device 100. In another embodiment, the BIOS 140 may comprise routines which the computing device 100 may execute during system backup or recovery. The BIOS 140 may further handle communications in the computing device 100, e.g., between software running on the computing device 100 and/or devices in the computing device 100, such as CPUs, disk drives, or printers, etc. The BIOS 140 may further comprise routines or drivers which the computing device 100 may execute to communicate with one or more components in the computing device 100.

In another embodiment, the computing device 100 may comprise a BIOS memory to store BIOS code or data. The BIOS memory may be implemented with non-volatile memory devices, such as read-only memory (ROM) devices, flash memory, and any other memories. The BIOS 140 may further contain a BIOS USB driver and other drivers. The BIOS 140 may be implemented in a firmware. In one embodiment, the BIOS 140 may comprise a legacy BIOS, extensible firmware interface (EFI) BIOS, or other BIOS. The chipset 130 may comprise a BIOS interface 124 that may access the BIOS 140 via a bus 142. While FIG. 1 shows the BIOS 140 in the computing device 100, some embodiments may employ other device to handle communication and/or perform system initialization in the computing device 100.

In one embodiment, the computing device 100 may communicate with one or more networks 170 via a network bus 172. The chipset 130 may comprise a network controller 126 to control the communication between the computing device 100 and the networks 170. The chipset 130 may further comprise one or more other component interfaces (not shown) to access the other components 160 via one or more buses 142 such as, for example, peripheral component interconnect (PCI) buses, accelerated graphics port (AGP) buses, universal serial bus (USB) buses, low pin count (LPC) buses, and/or other I/O buses.

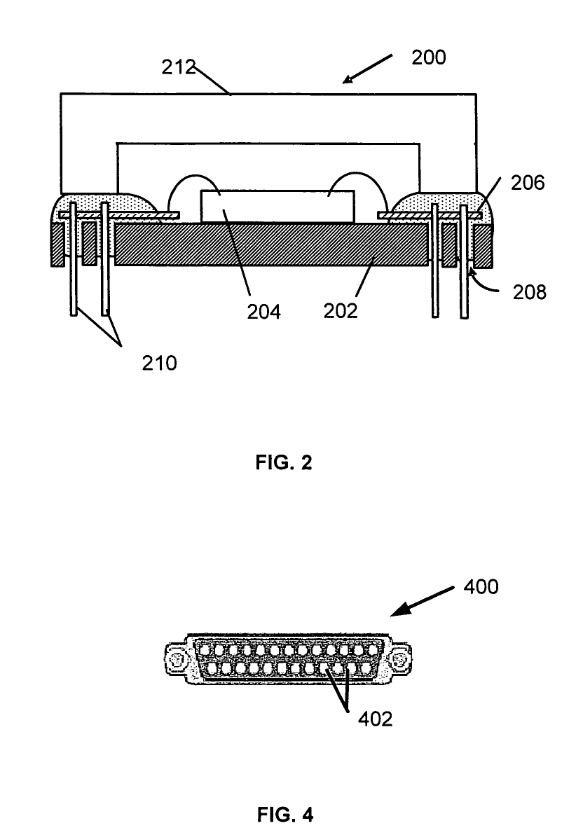

FIG. 2 illustrates an exemplary embodiment of an integrated circuit chip or package 200. In one embodiment, the chip 200 is configured with external interconnections such as one or more pins 210 on its lower side. For example, the pin 210 may be utilized to couple the chip 200 to a chipset or a motherboard (not shown) by a socket. In one embodiment, the set of pins may be arranged in line, grid array, queue, matrix or any other suitable arrangements.

Any suitable methods may be utilized to mount a pin 210 to the chip 200. In one embodiment, the pins 210 may be coupled to one or more conductive circuitry 206 that may each comprise a pin bonding site, pad, opening or aperture (not shown). The conductive circuitry 206 may be coupled with one or more IC devices 204 such as semiconductor circuits, dies on a substrate 202 that may be coupled to the IC devices 204 via wire bonds, bumps or any other interconnects. In one embodiment, the pins 210 may pass through the one or more circuitry 206. In another embodiment, the pins 210 may extend through the substrate 202 by openings or apertures 208. In another embodiment, the pins 210 may protrude from the chip 200. In yet another embodiment, a cover component 212 may be provided to protect the chip 200 or the IC devices 204. In another embodiment, an encapsulant or molding compound such as epoxy resin may be used to encapsulate IC devices or dies, substrates, or interconnects, in the chip 200. In another embodiment, a pin 210 may be soldered or brazed to the conductive circuitry 206 in the chip 200.

In one embodiment, the pin 210 may be formed from one or more shape memory alloys (SMA) or metals. In another embodiment, a protruded portion or lower end of the pin 210 may be made from one or more SMA. For example, the SMA may comprise one or more metals. In another embodiment, the SMA may revert to its original shapes under a temperature, e.g., a transformation temperature. For example, if a straight pin made from SMA is bent, the bent pin may become straight under a transformation temperature of the SMA. In another embodiment, the material for a pin 210 may further comprise one or more other metals such as copper, silver or tin, etc. The composition and/or percentage by weight of the SMA in pin material may be varied based on a desired mechanical and/or electrical performance. Examples of the SMA may comprise NiTi SMA, copper based SMA, or any other SMA. In another embodiment, the pin 210 may be coated with another metal or metals such as gold to enhance conductivity, solderability and/or adhesion. In another embodiment, a method similar to that for producing a copper pin may be utilized to provide the pin 210 made from SMA. Any suitable package or chips may utilize pins made from SMA, such as package in line (PIL) package, plastic leaded chip carrier (PLCC), thin small outline package (TSOP), plastic pin grid array (PPGA) package, flip chip package grid array (FCPGA) package, metal pin grid array package or any other suitable packages or chips.

In another embodiment, one or more system components of the computing system 100 of FIG. 1 may be provided on the chipset 120 or a motherboard (not shown). The one or more components configure with pins made from SMA to couple to the chipset 120 or the motherboard. Examples of the one or more components may comprise processors, memories, BIOS, controllers, storage devices and/or any other chip, firmware, package or component. In another embodiment, a server may be configured with the pins made from SMA to couple the server to a motherboard.

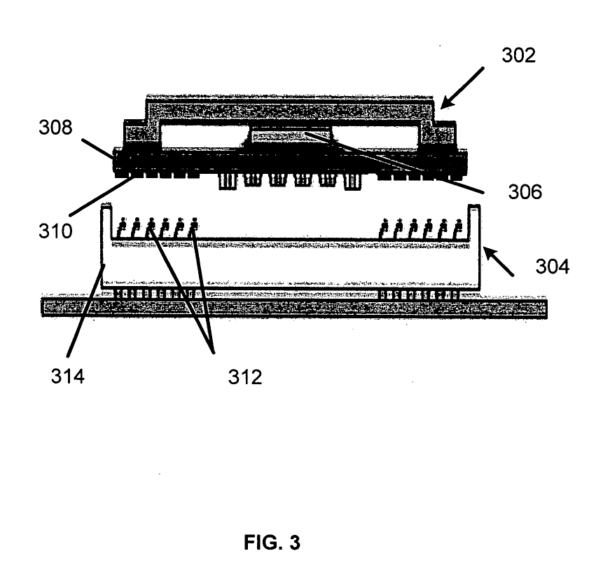

FIG. 3 illustrates another embodiment of a package that may utilize pins. In one embodiment, a package 302 such as a land grid array (LGA) package may be utilized. The package 302 may be coupled to a socket 304. As shown in FIG. 3, the package 302 may comprise one or more IC devices 306 such as semiconductor circuits in the package 302. The package 302 may further comprise a first substrate 308 that may be coupled to the IC devices 306. In another embodiment, the first substrate 308 may with one or more external interconnects such as lands or pads 310. Referring to FIG. 3, the socket 304 may comprise one or more pins 312. In one embodiment, a land 310 may be coupled to a pin 312 to couple the package 302 to the socket 304. In another embodiment, the socket 304 may comprise a second substrate 314 that may be configured with one or more external interconnects to couple to a printed circuit board (PCB) or a motherboard (not shown). The material as mentioned with regard to FIG. 2 may be used for the pins 312.

FIG. 4 illustrates an embodiment of a socket or port 400. In one embodiment, the socket or port 400 may comprise one or more pins 402 that may couple a device such as peripheral devices (not shown) to a computing system or another device (not shown). In one embodiment, the material as mentioned with regard to FIG. 2 may be utilized for the pins 402. In another embodiment, any suitable examples may be utilized for the socket or port 400, such as video graphic array (VGA) ports that may be used to link a computing system to a project or any other external monitor, I/O ports, serial ports, parallel ports, USB ports, battery sockets with contact pins or any other connectors.

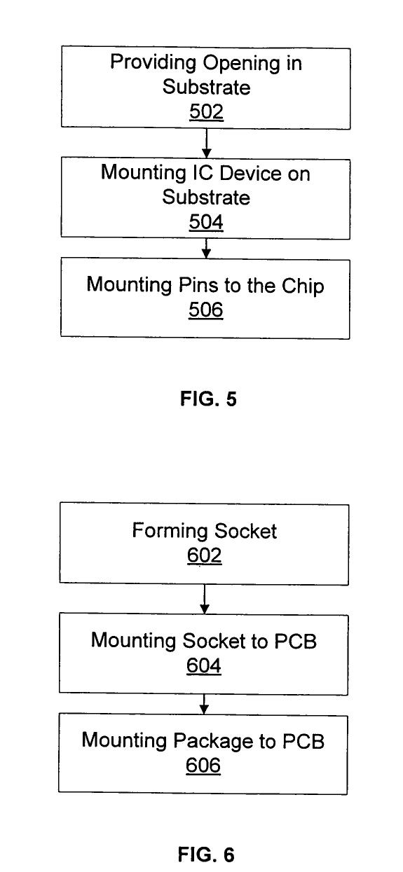

FIG. 5 illustrate an embodiment of a method that may be used to form the chip of FIG. 2. In block 602, one or more openings 208 may be formed in the substrate 202. In block 604, one or more IC devices 204 may be mounted on the substrate 202. The IC devices 204 may be coupled to the substrate 202, e.g., by conductive circuitry 206 provided on the substrate 206. In another embodiment, one or more openings or pads (not shown) may be formed in the conductive circuitry 206 to couple to the pins 210. The openings in the conductive circuitry 206 may be aligned with the openings in the substrate 202. In block 606, the pins 210 may be mounted to the chip 200 by the one or more openings in the conductive circuitry 206 and the substrate 202. In another embodiment, the pins 210 may be brazed or soldered to the one or more pads on the conductive circuitry 206. In another embodiment, a cover component 212 may be assembled on the chip 200.

FIG. 6 illustrates an embodiment of a method that may be used to form a chip that comprises the package 302 and the socket 304 of FIG. 3. In block 602, the socket 304 may be formed. In one embodiment, one or more pins 312 may be provided on a substrate 314 of the socket 304. The substrate 314 may be provided with one or more external interconnects (not shown). In block 604, the socket 304 may be mounted to a PCB or motherboard (not shown). In one embodiment, the socket 304 may be coupled to the PCB or motherboard by the one or more external interconnects. In block 606, the package 302 may be mounted to the socket 304. In one embodiment, a land or pad 310 on the substrate 308 may be arranged to couple to a pin 312 in the socket 304. In another embodiment, the IC device 306 may be mounted and coupled to the substrate 308 by one or more interconnects (not shown).

While the methods of FIGS. 5 and 6 are illustrated to comprise a sequence of processes, the method in some embodiments may perform illustrated processes in a different order. Further, while the embodiments of FIGS. 2, 3 and 4 are illustrates to comprise a certain number of dies, interconnects, substrates, pins, IC devices, chips, etc., some embodiments may apply to a different number and a different arrangement.

While certain features of the invention have been described with reference to embodiments, the description is not intended to be construed in a limiting sense. Various modifications of the embodiments, as well as other embodiments of the invention, which are apparent to persons skilled in the art to which the invention pertains are deemed to lie within the spirit and scope of the invention.

What is claimed is:

1. A system comprising:
a processor, and
a pin provided on the processor to couple the processor to a motherboard that supports the processor, wherein material for the pin comprises one or more shape memory alloys.

2. The system of claim 1, wherein the shape memory alloys comprises one or more from a group comprising NiTi shape memory alloys, and copper based shape memory alloys.

3. The system of claim 1, wherein the material for the pin further comprises one from a group comprising copper, silver, and tin.

4. The system of claim 1, comprising:
a basic input output system that comprises a pin to couple to the motherboard, the pin of the basic input output system comprises one or more shape memory alloys.

5. The system of claim 1, comprising:
a storage device, wherein a pin made from one or more shape memory alloys is provided on the storage device to couple the storage device to the motherboard.

6. The system of claim 1, comprising:
a memory controller provided on a chipset that is coupled to the processor, wherein the memory controller comprises a pin made from one or more shape memory alloys to couple to the chipset.

7. The system of claim 1, comprising:
a server that comprises a pin to coupled to the motherboard, wherein the pin of the server is made from one or more shape memory alloys.

8. The system of claim 1, comprising:
one or more system components to couple to the motherboard, wherein each system component is provided with a set of pins, materials for the pins comprising one or more shape memory alloy.

9. An integrated circuit chip comprising:
one or more IC devices, and
one or more pins coupled to the one or more IC devices, wherein material for the pins comprises one or more shape memory alloys.

10. The integrated circuit chip of claim 9, wherein the one or more shape memory alloys comprise one or more from a group comprising NiTi shape memory alloys, and copper based shape memory alloys.

11. The integrated circuit chip of claim 9, wherein the material for the pin further comprises one from a group comprising copper, silver, and tin.

12. The integrated circuit chip of claim 9, wherein the one or more pins are provided in a socket to couple the one or more IC devices to a printed circuit.

13. The integrated circuit chip of claim 9, wherein the chip comprises one of a group that comprises package in line package, plastic leaded chip carrier packages, thin small outline packages, plastic pin grid array packages, flip chip package grid array packages, metal pin grid array packages, land grid array packages.

14. A method, comprising:
providing a integrated circuit chip, and
mounting one or more pins to the integrated circuit chip, wherein material for the pins comprises one or more shape memory alloys.

15. The method of claim 14, wherein the one or more shape memory alloys comprise one or more from a group comprising NiTi shape memory alloys, and copper based shape memory alloys.

16. The integrated circuit chip of claim 14, wherein the material for the pin further comprises one from a group comprising copper, silver, and tin.

17. A socket, comprising:
one or more pins, wherein material for the pins comprises one or more shape memory alloys.

18. The socket of claim 17, wherein socket comprises one from a group that comprises video graphic array (VGA) ports, I/O ports, serial ports, parallel ports, USB ports, battery sockets.
